(19) United States
(12) Patent Application Publication
(10) Pub. No.: US 2024/0405102 A1
(43) Pub. Date: Dec. 5, 2024

(54) ELECTRON CONFIGURATION METHOD AND ELECTRON CONFIGURATION DEVICE

(71) Applicant: Hitachi, Ltd., Tokyo (JP)

(72) Inventor: Naoto SATO, Tokyo (JP)

(73) Assignee: Hitachi, Ltd., Tokyo (JP)

(21) Appl. No.: 18/677,022

(22) Filed: May 29, 2024

(30) Foreign Application Priority Data
May 30, 2023 (JP) 2023-089123

(51) Int. Cl. H01L 29/66; B82Y 10/00; B82Y 20/00; G06N 10/20; G06N 10/40; H01L 29/76

(52) U.S. Cl. CPC H01L 29/66977; B82Y 10/00; B82Y 20/00; G06N 10/20; G06N 10/40; H01L 29/7613

(57) ABSTRACT

The technology provided by the present invention makes it possible to obtain desired calculation results efficiently while appropriately avoiding a deadlock in qubit operations performed in a situation where a large number of qubits are arranged. An electron configuration device formed by a quantum computer includes a bus area, an aisle area, and a seat area in a qubit array. In an environment where the seat area and the bus area are connected by the aisle area, the electron configuration device is configured such that a first qubit initially arranged in a predetermined seat area reaches the bus area through the aisle area connected to the seat area and moves through the bus area to a position adjacent to a second qubit to be operated on.

### BACKGROUND OF THE INVENTION

### 1. Field of the Invention

The present invention relates to an electron configuration method and an electron configuration device.

### 2. Description of the Related Art

Implementation of a quantum computer requires implementation of qubits (quantum bits) that achieve the superposition of 0 and 1 values.

For example, in a silicon electronic quantum computer, the qubits are implemented by implementation of quantum dots through the use, for example, of a field-effect transistor and confinement of electrons in the implemented quantum dots.

Arithmetic operations (gate operations) on the qubits implemented in the above manner are performed by application of a static magnetic field or an electromagnetic pulse to the qubits.

These arithmetic operations require control lines for applying voltage and current to electrodes that control the qubits. In the case of a design that individually arranges the control lines for each qubit, the number of such control lines will increase in association with an increase in the number of qubits.

Meanwhile, when spatial constraints on a control line arrangement area are taken into consideration, a problem may occur because such spatial constraints make it extremely difficult to implement a large number of qubits.

The above problem may effectively be solved by simultaneous control of a plurality of qubits through the use of a single control line as described in JP-2021-027142-A. According to the technology disclosed in JP-2021-027142-A, qubits are arranged in an array, and a common control line is provided on a column or row basis. This control line makes it possible to perform operations on the qubits.

More specifically, the disclosed technology relates to an electron configuration device including a first layer and a second layer. The first layer is disposed on a fin. The second layer is disposed on the first layer. The fin includes a qubit array and an interaction array. The qubit array is an array of a plurality of qubits that are arranged in a line in a first direction. The interaction array is an array of a plurality of inter-qubit interactions that are arranged in a line in the first direction. The qubit array and the interaction array are arranged alternately in a second direction different from the first direction. The first layer includes a first gate electrode array and a second gate electrode array. The first gate electrode array is arranged in the first direction to control the qubits in the qubit array. The second gate electrode array is arranged in the first direction to control the inter-qubit interactions in the interaction array. The second layer includes a third gate electrode array and a fourth gate electrode array. The third gate electrode array is arranged in the second direction. The fourth gate electrode array is arranged adjacent to the third gate electrode array in the second direction. The third gate electrode array and the fourth gate electrode array control some of the plurality of qubits and some of the plurality of inter-qubit interactions, respectively.

### SUMMARY OF THE INVENTION

According to the above-described conventional technology, the control line is common for each column or row. Thus, when an arithmetic operation is performed on a certain qubit, the same arithmetic operation is performed on unrelated qubits in the same column or row. As a result, a new problem arises in that an unexpected different calculation result is obtained.

In view of the above, the above problem might be solved by utilizing a qubit movement operation in a silicon electronic quantum computer.

The qubit movement operation is an operation that is performed to spatially move electrons forming a qubit to an adjacent quantum dot (an empty quantum dot where no electrons are placed).

The above-mentioned movement operation makes it possible to isolate unrelated qubits from the qubits to be controlled. Therefore, unnecessary influence on qubits can be reduced.

Further, primitive operations in a quantum computer include a one-qubit operation and a two-qubit operation. The one-qubit operation is performed to operate on one qubit, and the two-qubit operation is performed to cause two qubits to interact with each other.

In order to implement the two-qubit operation, it is necessary to place two target qubits adjacent to each other. However, only a limited number of qubits can be placed adjacent to each other. Thus, in a quantum program using a large number of qubits, it might be difficult to place a certain number of qubits adjacent to each other.

The qubit movement operation is also an effective way to solve the above problem. In a case where the two-qubit operation is performed on two qubits that are not placed adjacent to each other, the qubits can be placed adjacent to each other by moving the electrons in one (or both) of the qubits by the above-mentioned movement operation.

The above-mentioned movement operation is implemented by application of a voltage to the electrodes, as is the case with an arithmetic operation. Therefore, there is such a constraint that the movement operation is performed even on unrelated electrons in the same column or row as the electrons to be moved.

Consequently, in order to move the electrons to target positions, it is necessary to establish a movement operation procedure by considering the above constraint.

For example, in a case where electron A, which is to be moved, is moved downward in order to be placed adjacent to electron B (see FIG. 4), electron C, which is in the same row as electron A, also moves downward. However, since electron D exists in the destination of electron C, performing the above-mentioned movement operation causes electron C to collide with electron D. As a result, quantum information may not be maintained properly. Thus, in order to place electrons A and B adjacent to each other, it is necessary to establish another movement operation procedure.

As described above, under the above constraint, some movement operations cannot be performed in order to avoid electron collisions. Further, a combination of executable movement operations may make it impossible to perform a particular qubit operation.

For example, the example in FIG. 4 illustrates two different movement operations for performing the two-qubit operation on electrons A and B. No matter which movement operation is selected, the two-qubit operation can be performed on electrons A and B. However, if the operation depicted in FIG. 4 is selected, the resulting arrangement will be such that the two-qubit operation cannot be performed on electrons C and D.

As described above, in a case where a plurality of qubit operations are performed under the above-mentioned constraint, there is a possibility of falling into a deadlock in which a desired qubit operation cannot be performed.

For example, the following technology has been proposed as a conventional technology (refer to Li, Gushu, Yufei Ding, and Yuan Xie; “Tackling the Qubit Mapping Problem for NISQ-Era Quantum Devices;” Asplos 2019; arXiv: 1809.02573) that deals with a similar problem. According to this conventional technology, a SWAP operation, which is an arithmetic operation for exchanging quantum information between two qubits, is executed in order to place specific qubits adjacent to each other in a superconducting qubit array.

However, the method used by the above conventional technology is applicable to the qubit array on the assumption that the qubit array has a structure for allowing one qubit to reach another qubit. Thus, no matter what procedure is used to execute the SWAP operation, there will be no deadlock (for example, the number of times the SWAP operation is executed is dependent on the procedure used for operation execution). Therefore, the method used by the above conventional technology does not include any measures to avoid a deadlock.

Further, the method used by the above conventional technology does not assume that arithmetic operations are performed on a column or row basis. Thus, it is difficult to apply this method directly to problems addressed by an embodiment of the present invention. As described above, the conventional technology is unable to avoid falling into a deadlock in which a desired qubit operation cannot be performed.

Hence, the present invention has been made to provide a technology that is able to obtain desired calculation results efficiently while appropriately avoiding a deadlock in qubit operations performed in a situation where a large number of qubits are arranged.

In order to address the above-described problems, according to an aspect of the present invention, there is provided an electron configuration method used by a quantum computer that includes a bus area, an aisle area, and a seat area in a qubit array formed by a plurality of quantum dots capable of storing electrons. The bus area transversely or longitudinally crosses the qubit array. The aisle area is orthogonal to the bus area in the qubit array. The seat area is positioned between the bus area and the aisle area and used as an area where qubits are arranged. The electron configuration method includes causing, in an environment where the seat area and the bus area are connected by the aisle area, the quantum computer to move a first qubit initially arranged in a predetermined seat area to the bus area through the aisle area connected to the seat area, and move the first qubit through the bus area to a position adjacent to a second qubit to be operated on.

According to another aspect of the present invention, there is provided an electron configuration device formed by a quantum computer. The electron configuration device includes a bus area, an aisle area, and a seat area in a qubit array formed by a plurality of quantum dots capable of storing electrons. The bus area transversely or longitudinally crosses the qubit array. The aisle area is orthogonal to the bus area in the qubit array. The seat area is positioned between the bus area and the aisle area and used as an area where qubits are arranged. In an environment where the seat area and the bus area are connected by the aisle area, the electron configuration device allows a first qubit initially arranged in a predetermined seat area to reach the bus area through the aisle area connected to the seat area, and moves the first qubit through the bus area to a position adjacent to a second qubit to be operated on.

The technology provided by the present invention makes it possible to obtain desired calculation results efficiently while appropriately avoiding a deadlock in qubit operations performed in a situation where a large number of qubits are arranged.

### BRIEF DESCRIPTION OF THE DRAWINGS

FIG. 1 is a diagram illustrating an example of a configuration of a qubit array in an embodiment of the present invention;

FIG. 2A is a diagram illustrating an example of rules of electron movement in the embodiment;

FIG. 2B is a diagram illustrating an example of rules of electron movement in the embodiment;

FIG. 3A is a diagram illustrating an example of block control in the embodiment;

FIG. 3B is a diagram illustrating an example of block control in the embodiment;

FIG. 3C is a diagram illustrating an example of block control in the embodiment;

FIG. 4 is a diagram illustrating an example of electron movement in a deadlock in the embodiment;

FIG. 5 is a diagram illustrating an example of a configuration of a quantum computer system in the embodiment;

FIG. 6 is a diagram illustrating an example of an electron configuration in the qubit array in the embodiment;

FIG. 7 is a diagram illustrating an example of electron movement in the embodiment;

FIG. 8 is a flowchart illustrating an electron configuration method according to the embodiment;

FIG. 9 is a diagram illustrating an example of electron movement in the embodiment;

FIG. 10 is a diagram illustrating an example of qubit operation in the embodiment;

FIG. 11 is a diagram illustrating a detailed example of electron movement in the embodiment;

FIG. 12 is a diagram illustrating a detailed example of electron movement in the embodiment;

FIG. 13 is a diagram illustrating a detailed example of electron movement (return to original position) in the embodiment;

FIG. 14 is a diagram illustrating a detailed example of electron movement (return to original position) in the embodiment;

FIG. 15 is a diagram illustrating a detailed example of electron movement (crash) in the embodiment;

FIG. 16 is a diagram illustrating another example of a configuration (increased aisle area) of the qubit array in the embodiment;

FIG. 17 is a diagram illustrating another example of a configuration (increased bus area) of the qubit array in the embodiment;

FIG. 18 is a diagram illustrating another example of a configuration (fixed operation area) of the qubit array in the embodiment;

FIG. 19 is a diagram illustrating an example of electron movement in the embodiment; and

FIG. 20 is a diagram illustrating a detailed example of electron movement in the embodiment.

### DESCRIPTION OF THE PREFERRED EMBODIMENTS

### Configuration of Qubit Array and Rule of Movement

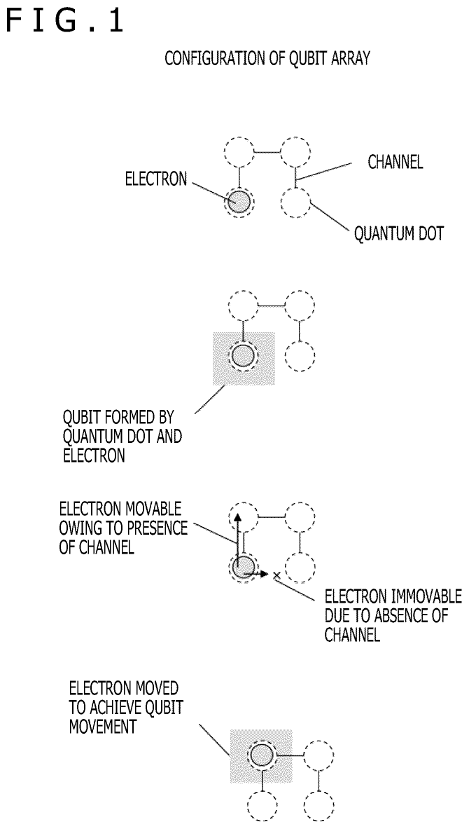

Embodiments of the present invention will now be described in detail with reference to the accompanying drawings. FIG. 1 is a diagram illustrating an example of a configuration of a qubit array that is implemented by an electron configuration device according to an embodiment of the present invention. An electron configuration device 100 depicted in FIG. 1 is formed by a quantum computer that is able to obtain desired calculation results efficiently while appropriately avoiding a deadlock in qubit operations performed in a situation where a large number of qubits are arranged.

As illustrated in FIG. 1, the qubit array in the present embodiment is assumed to have a configuration in which a plurality of quantum dots are appropriately being connected to each other by channels, and qubits are configured by electrons being arranged in the quantum dots configured as described above.

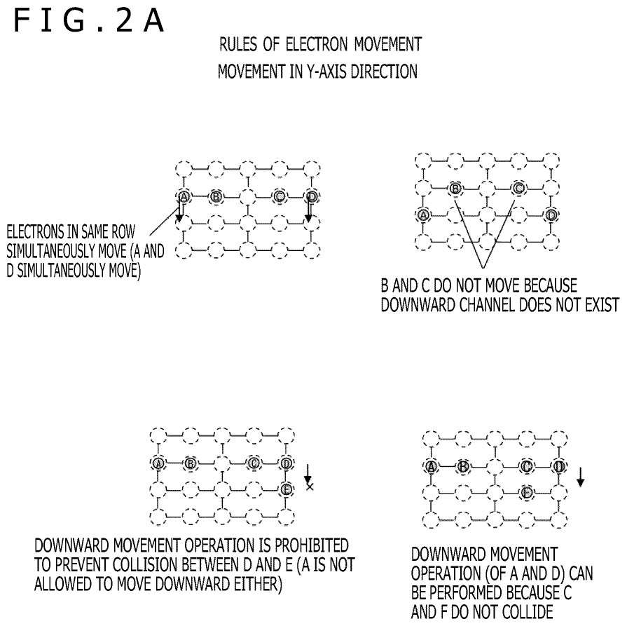

The electrons forming a qubit can move to adjacent quantum dots through the channels. However, such movement is allowed only when the rules of movement illustrated in FIGS. 2A and 2B are observed, and the mode of movement is restricted. In the case, for example, of movement in the Y-axis direction (the longitudinal direction in a lattice forming the qubit array in FIG. 2A), moving the electrons in a certain qubit (qubit “A” in FIG. 2A) causes the other qubits (qubits “B,” “C,” and “D” in FIG. 2A) in the same row to move at the same time.

However, it is necessary that source quantum dots and destination quantum dots be connected by the channels. If no channel exists, the electrons do not move.

Further, if electrons already exist in the destination quantum dots, the electrons are unable to move because they would collide with each other. That is, the movement is allowed in a situation where the source and destination quantum dots are connected by the channels and the destination quantum dots are unoccupied by the electrons.

The above-mentioned movement restriction and mode are the same as those in the case of the X-axis direction as depicted in FIG. 2B. The electrons in the same column move simultaneously on the condition that the quantum dots are connected by the channels and that no electrons exist in the destination quantum dots.

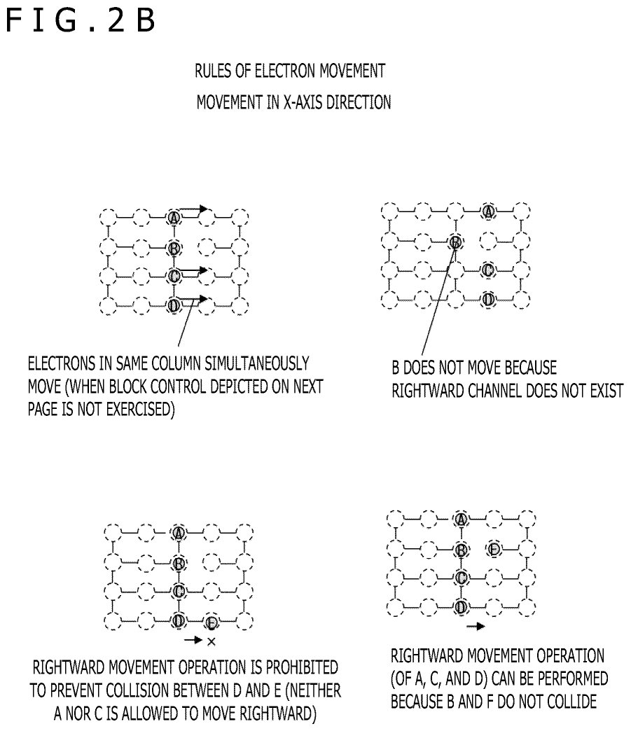

However, what is generally called block control technology (a known technology) may be adopted as an exceptional operation technology for the movement restriction described above. As depicted in FIGS. 3A to 3C, the block control technology allows only specific electrons to move in the X-axis direction when the source of movement is a “column without a longitudinal channel (normal column)” and the destination of movement is a “column with a longitudinal channel,” and allows the electrons to move when the source of movement is a “column with a longitudinal channel” and the destination of movement is a “column without a longitudinal channel (normal column).”

Additionally, when such block control is exercised in a case where the electrons are adjacent, for example, in a case where qubit electron “2” and qubit electron “4” in FIGS. 3B and 3C are adjacent, the electrons can move on the condition that no electrons exist in each quantum dot in a column behind the destination quantum dot column (longitudinal channel column). However, in a case where the destination longitudinal channel column is the end column of the array, block control can be exercised even if the electrons are adjacent, that is, the electrons can move.

### Conventional Situation Resulting in Deadlock

The quantum computer (electron configuration device) repetitively moves target electrons existing in a quantum dot to a desired position (a quantum dot adjacent to a quantum dot for electrons targeted for qubit operation) under the above-mentioned movement restriction. However, if an attempt is made to move the electrons in the above manner on an ad hoc basis, a deadlock may occur, that is, the electrons may become unable to move due to the movement restriction in the middle of movement or at the destination.

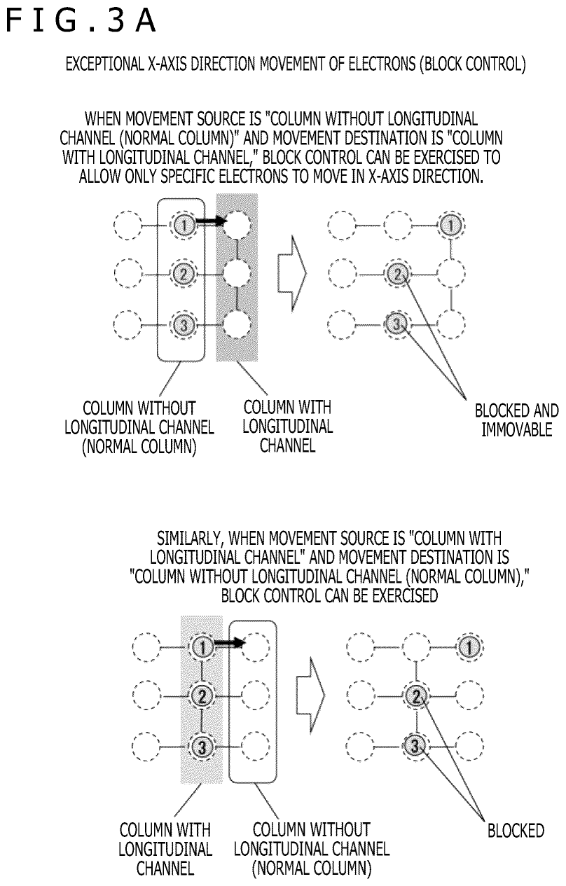

The above-mentioned state is illustrated in FIG. 4. In any case, the movement restriction is based on the definition of block control, although the situation resulting in such a deadlock can efficiently and properly be avoided by adopting an electron configuration method according to the present embodiment.

### Example of Configuration of Electron Configuration Device

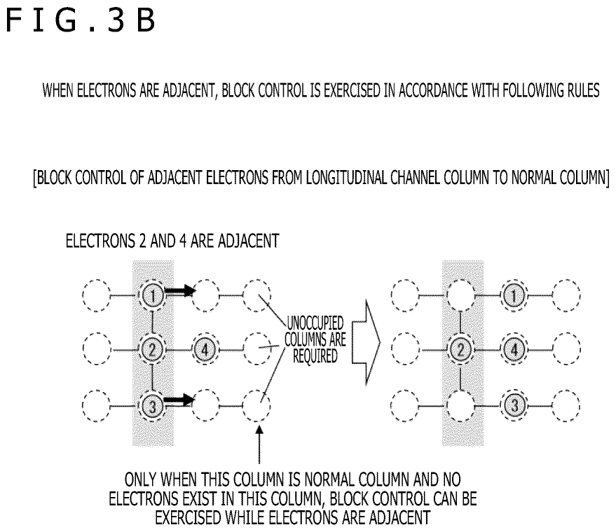

It is assumed that the electron configuration device 100 according to the present embodiment is formed by either a quantum computer 100 or a quantum compiler device 200 as depicted in FIG. 5 (a system formed by the coordination between these devices may obviously be defined as the electron configuration device).

For example, the quantum computer 100 includes a qubit array control section 110 that provides electron movement control in a qubit array 101. Meanwhile, the quantum compiler device 200 includes a qubit control procedure generation section 210 that generates a qubit control procedure 203 based on structure information 201 regarding the qubit array 101 (e.g., information regarding a bus area, an aisle area, and a seat area) and on qubit operation information 202 (quantum program).

The qubit control procedure 203 is given to the qubit array control section 110 of the quantum computer 100, and used as procedure information regarding electron movement operations in actual qubits. The procedure information includes information regarding each of the bus, aisle, and seat areas on a qubit array, and procedure information regarding the movement of a qubit (electrons forming the qubit) in the order of seat area, aisle area, and bus area. That is, the quantum computer 100 moves the qubits in the order of seat area, aisle area, and bus area in reference to the procedure information regarding the above-mentioned movement operations.

It should be noted that the hardware configuration of the quantum computer 100 and the quantum compiler device 200 is assumed to be based, for example, on a silicon quantum dot system (what is generally called a silicon quantum computer). However, the hardware configuration need not necessarily be based on the silicon quantum dot system.

### Configuration and Movement of Electrons in Qubit Array

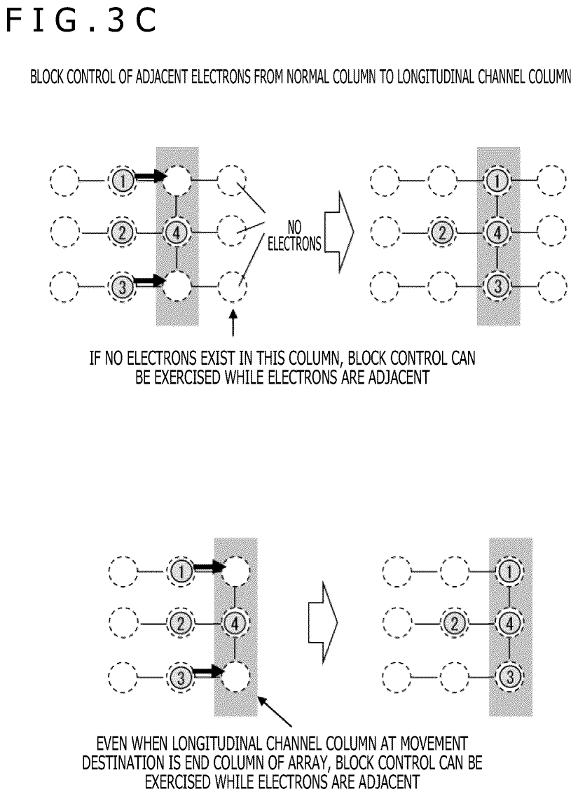

FIG. 6 illustrates an example of an electron configuration in a qubit array in the present embodiment. As illustrated in FIG. 6, the qubit array in the present embodiment has a configuration including the bus area and the aisle area. The bus area transversely crosses a qubit storage area. The aisle area allows each qubit to access the bus area. An area surrounded by the bus area and the aisle area is defined as the seat area. The seat area provides a fixed position (initial placement position) for electrons.

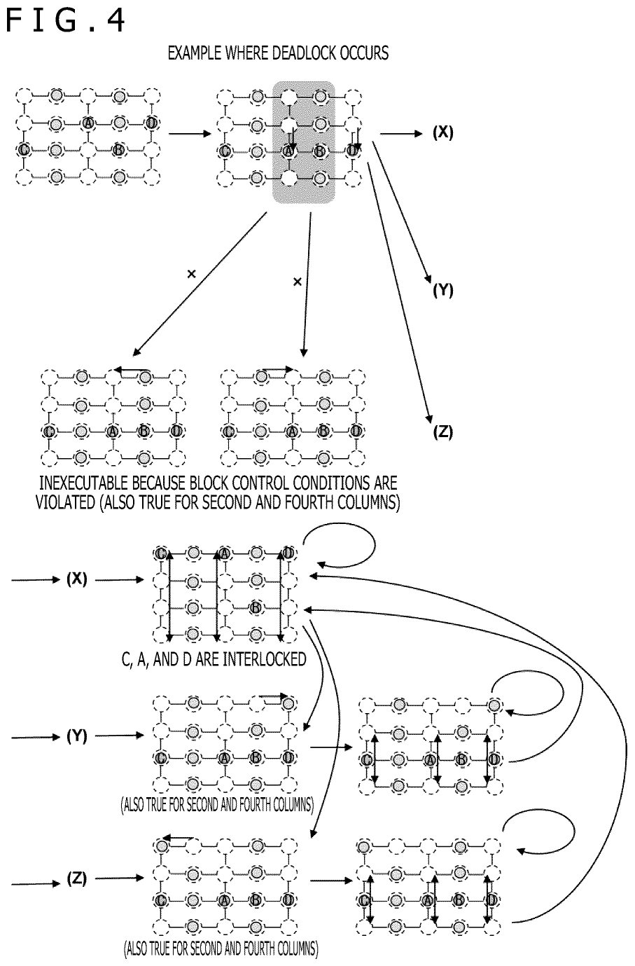

The electrons in the above-described state move as depicted in the example of electron movement in FIG. 7. For example, a qubit electron (an electron in the second row of the first column) moves through the bus area and the aisle area to a position (the sixth row of the sixth column in FIG. 7) adjacent to another qubit (in the sixth row of the seventh column in FIG. 7).

Further, after execution of an arithmetic operation, the electron returns to the original seat area (to the second row of the first column) through the same route. In this manner, it is guaranteed that the electron is able to return to a previous position (the original position in the seat area) after execution of an arithmetic operation. Thus, there is no possibility of falling into a deadlock due to conventional ad hoc movement operations.

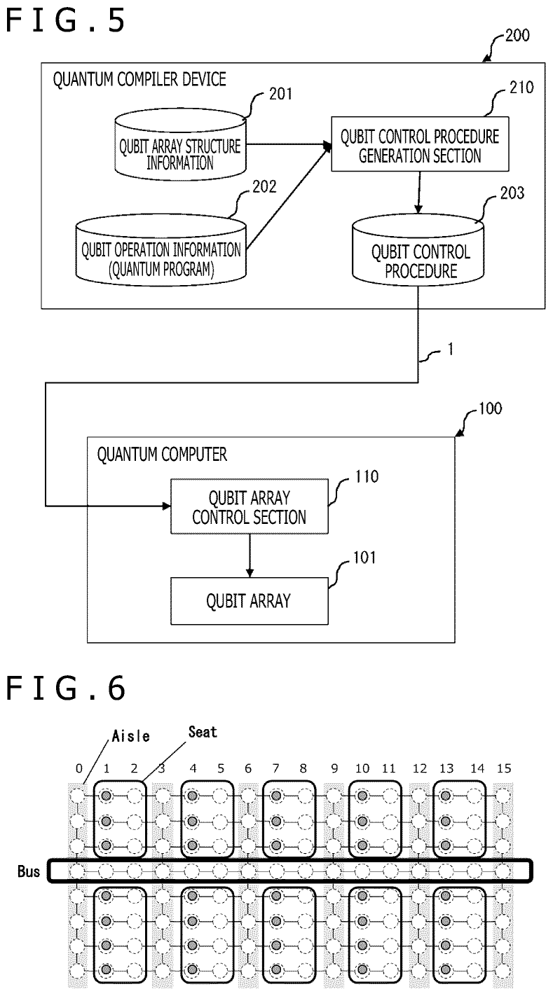

The mode of such movement is depicted in the flowchart of FIG. 8. Specifically, the quantum computer 100 acquires the qubit control procedure 203 from the quantum compiler device 200 (s10). Obviously, the quantum computer 100 may have the same configuration and functions as the quantum compiler device 200 and generate the qubit control procedure 203 by itself. Similarly, there may be a situation where the quantum compiler device 200 has the configuration and functions of the quantum computer 100 and performs the processing depicted in the flowchart.

It should be noted that the above-mentioned qubit control procedure 203 includes configuration information and procedure information. The configuration information defines the bus area, which transversely or longitudinally crosses the qubit array, the aisle area, which is orthogonal to the bus area in the qubit array, and the seat area, which is positioned between the bus area and the aisle area to serve as the area where the qubits are arranged, and indicates that the aisle area connects the seat area to the bus area. The procedure information describes the procedure for moving desired electrons to quantum dots in the qubit array in the above-described configuration.

Further, based on the qubit control procedure 203 acquired in s10, the quantum computer 100 causes a first qubit initially arranged in a predetermined seat area to reach the bus area through the aisle area connected to the seat area (s11).

Further, the quantum computer 100 moves the qubit which has reached the bus area in s11, through the bus area to a quantum dot positioned adjacent to a second qubit to be operated on (s12).

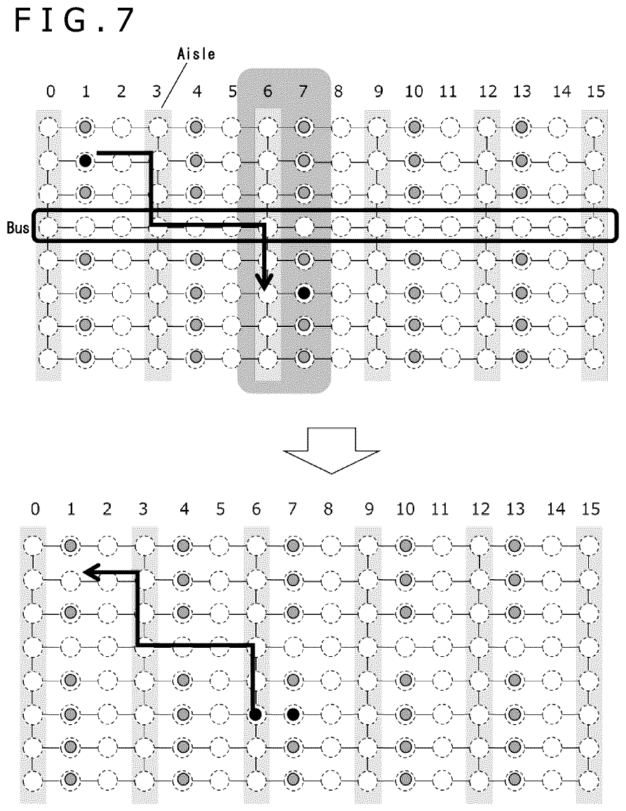

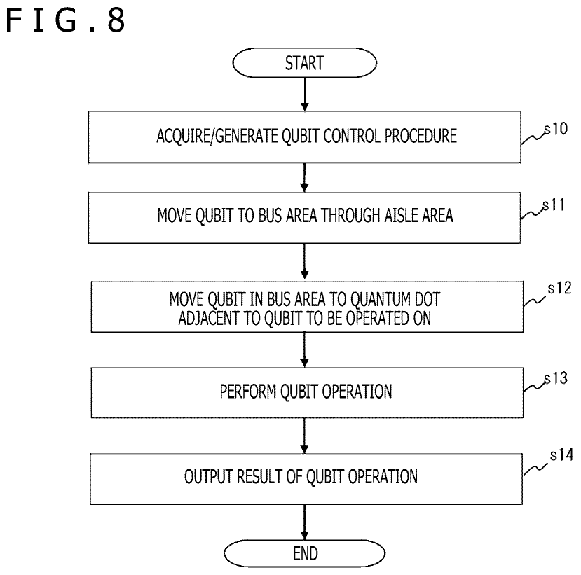

Moreover, the quantum computer 100 performs a qubit operation (e.g., a qubit operation depicted in FIG. 10) through the use of the qubit adjacently positioned in s12 (s13), then, for example, outputs the result of the qubit operation (s14), and ends the processing. It is assumed that the quantum computer 100 subsequently returns the qubit to its original position through the same route. It should be noted that, instead of using the above-described movement method, the qubit may be returned to its original position by being caused to crash against another qubit as depicted in FIG. 9.

In any case, any electron can move from the initial position (original position) to a position adjacent to any other electron and subsequently return to the initial position, by moving and returning to the original position in accordance with the above-described operation method.

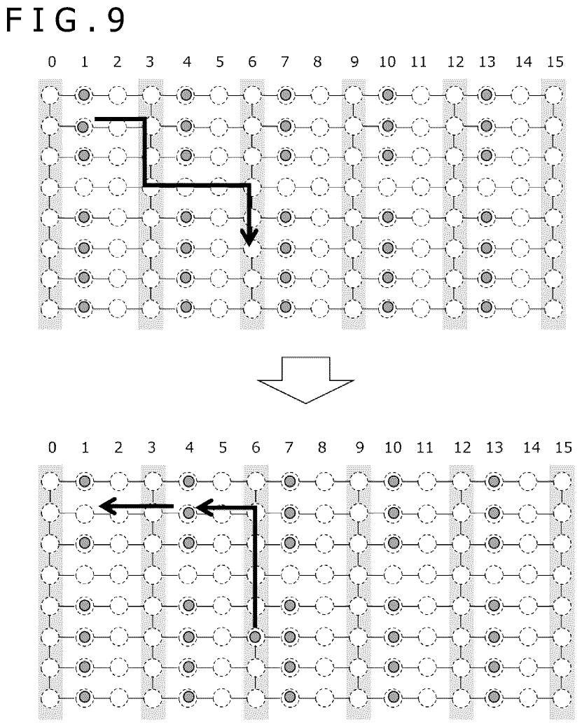

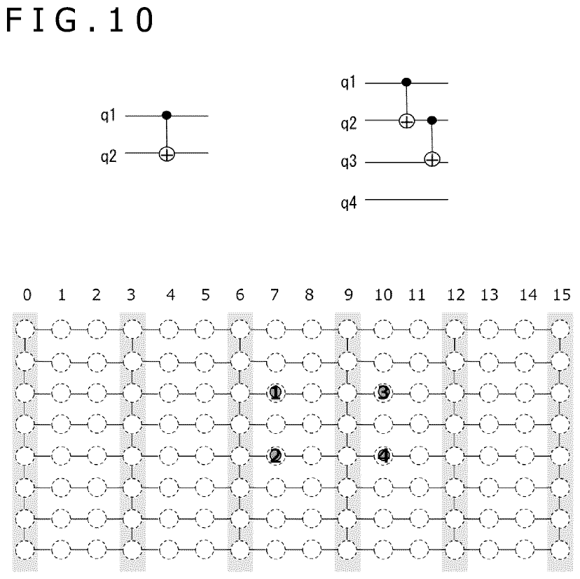

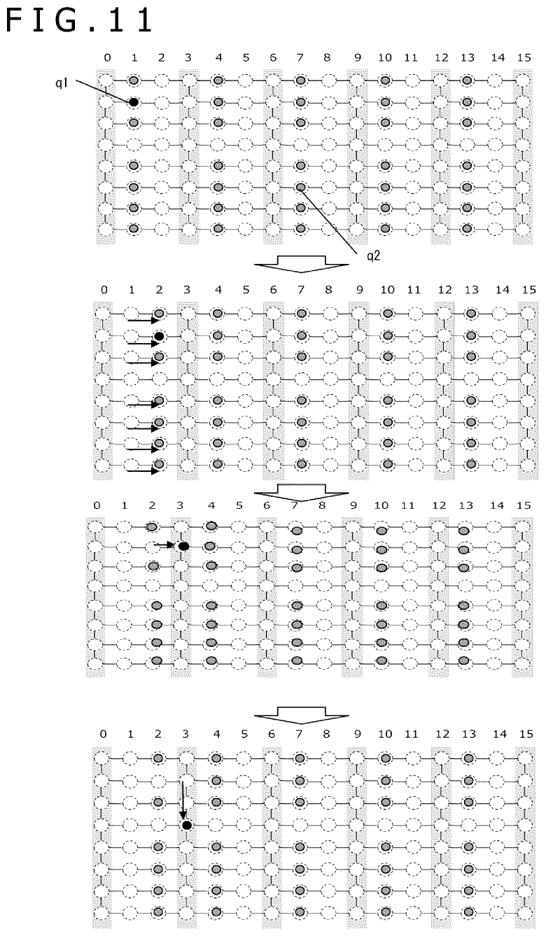

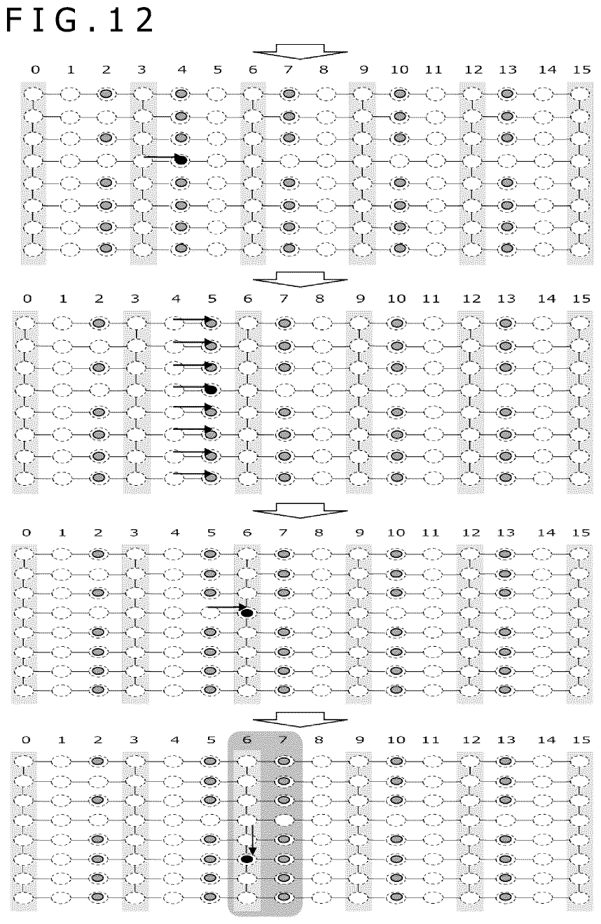

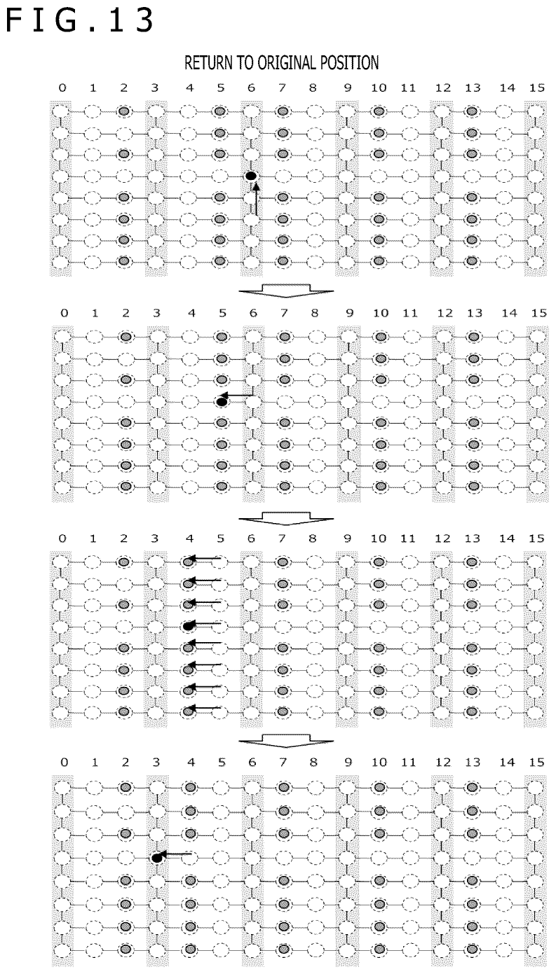

Examples of processing performed in s13 of the above flowchart, that is, a movement procedure (FIGS. 11 and 12) for the execution of qubit operation (FIG. 10) and subsequent return to the original position (FIGS. 13 to 15), are illustrated in FIGS. 11 to 15. The illustrated examples depict a case where qubit “q1,” which exists in the second row of the first column (original position), is allowed to move to a quantum dot adjacent to qubit “q2,” which is to be operated on, under the above-mentioned movement restriction. Further, the depicted movement is naturally based on the principle of simultaneous movement of electrons in the X-axis and Y-axis directions.

### Increase of Aisle Area and Bus Area

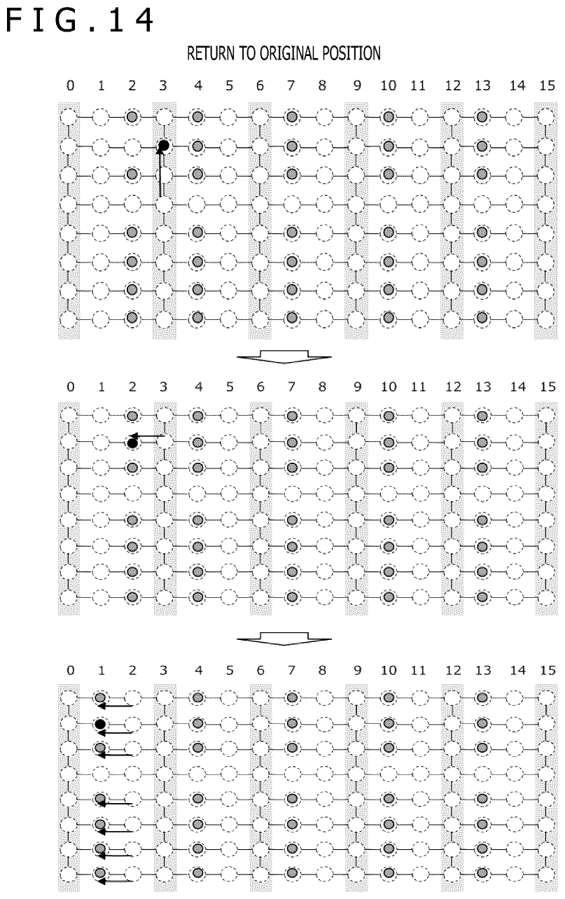

FIG. 16 illustrates another example of a configuration (increased aisle area) of the qubit array in the present embodiment. While the above-mentioned example assumes that qubit movement is performed by arranging the aisle area in every third column in the qubit array, the aisle area may alternatively be arranged in every other column.

When the above-described configuration is adopted, the restriction on qubit movement operation is reduced as compared to a case where the aisle area is arranged in every other column. Thus, it can be expected that the efficiency of movement increases.

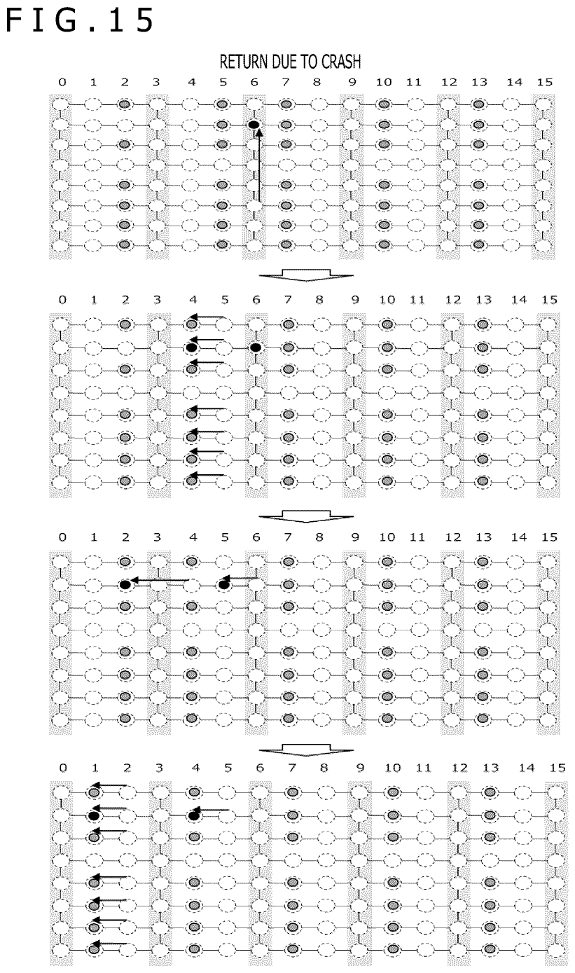

Similarly, the bus area may be increased as depicted in FIG. 17. While the above-mentioned example assumes that only one bus area is arranged in the qubit array, the example depicted in FIG. 17 assumes that a total of two bus areas are arranged in every third row.

When the above-described configuration is adopted, the constraint on qubit movement operation is reduced as compared to a case where only one bus area is arranged. Therefore, it can be expected that the efficiency of movement increases.

### Fixed Operation Area

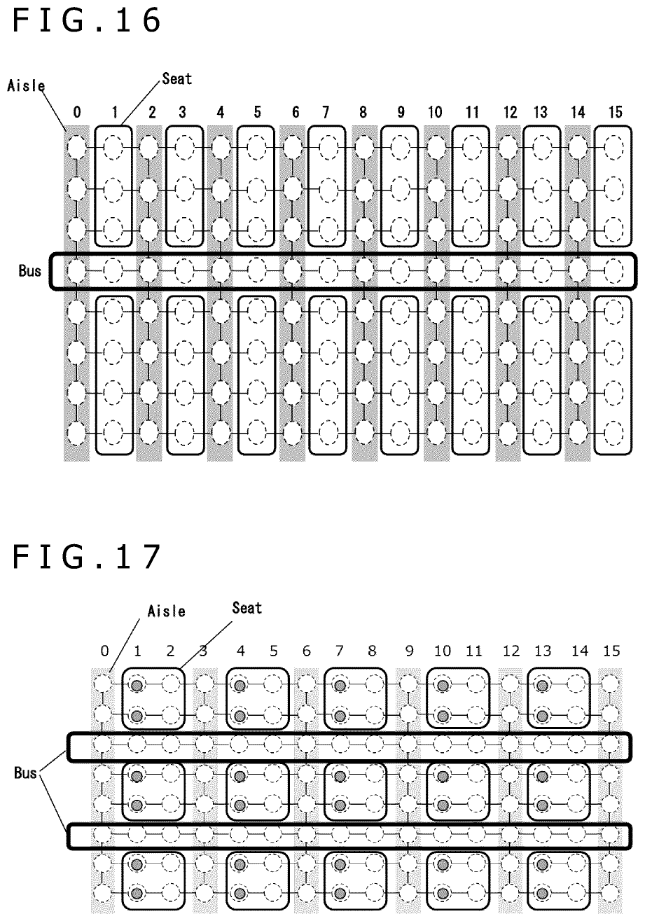

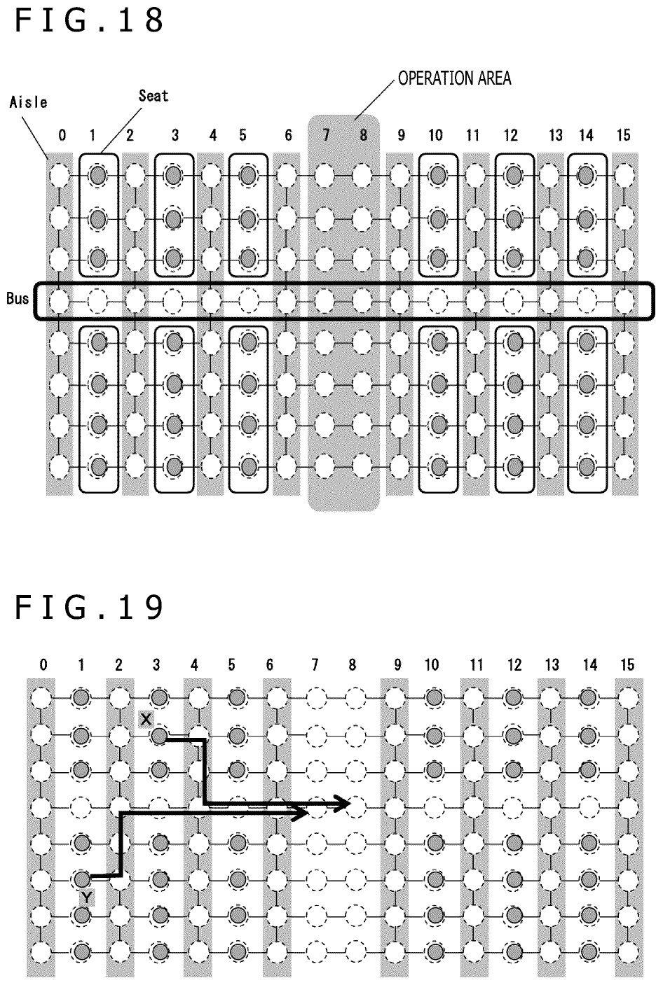

Here, it is assumed that a qubit operation area in the qubit array is fixed, for example, in the seventh and eighth columns as depicted in FIG. 18. For example, when there are qubit X (the qubit in the second row of the third column), which is to be moved, and qubit Y (the qubit in the sixth row of the first column), which is to be operated on, the quantum computer 100 moves both of qubits X and Y to a fixed area (seventh column, eighth column) designated as the qubit operation area.

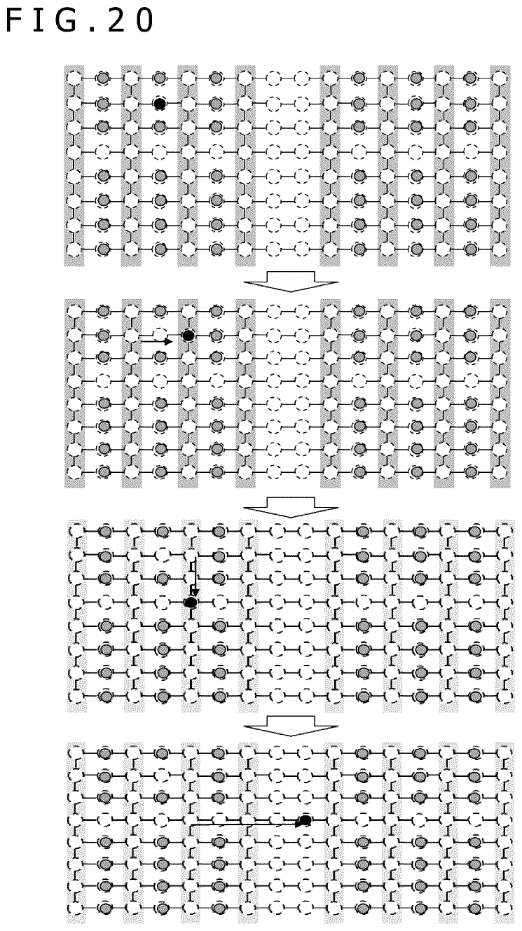

Qubit X, which is to be moved, is transferred to the fourth row of the eighth column, and qubit Y, which is to be operated on, is transferred to the fourth row of the seventh column. That is, electron transfer occurs in such a manner that qubits X and Y move to quantum dots adjacent to each other. Further, while a specific operation example of movement is depicted in FIG. 20, the electron transfer itself occurs in such a manner that qubits X and Y reach the bus area through the aisle area connected to the seat area at the original position and move to predetermined positions in the fixed area through the bus area under the previously mentioned constraint.

While the best mode for implementing the present invention has been specifically described above, the present invention is not limited to the described best mode, and may be modified in various ways without departing from the spirit and scope of the present invention.

The description in this document clarifies at least the following: The electron configuration method according to the present embodiment may cause the quantum computer to move the first qubit to an aisle area connected to a seat area of the second qubit through the bus area, and then move the first qubit through the aisle area to a position adjacent to the second qubit.

According to the above, electrons can smoothly be moved through the aisle area to a position (a quantum dot) adjacent to a qubit to be operated on.

Further, the electron configuration method according to the present embodiment may cause the quantum computer to move the second qubit to the bus area through an aisle area connected to the seat area, and, in the bus area, place the second qubit adjacent to the first qubit.

According to the above, a qubit to be moved and a qubit to be operated on can be placed adjacent to each other in a bus area where movement is likely to be easy. This makes it possible to perform efficient qubit operations.

Moreover, the electron configuration method according to the present embodiment may cause the quantum computer to move the first qubit to the bus area through an aisle area connected to the seat area, then move the first qubit to the aisle area connected to the seat area of the second qubit through the bus area, move the second qubit to the aisle area connected to the seat area, and, in the aisle area connected to the seat area of the second qubit, place the second qubit adjacent to the first qubit.

According to the above, a qubit to be moved and a qubit to be operated on can be placed adjacent to each other in an aisle area where movement is likely to be easy. This makes it possible to perform efficient qubit operations.

Moreover, the electron configuration method according to the present embodiment may cause the quantum computer to retain, in the qubit array, an arithmetic operation area where arithmetic operations can be performed on qubits, move the first qubit to the bus area through an aisle area connected to the seat area, then move the first qubit to the arithmetic operation area through the bus area, move the second qubit to the bus area through the aisle area connected to the seat area, then move the second qubit to the arithmetic operation area through the bus area, and thus, in the arithmetic operation area, place the second qubit adjacent to the first qubit.

According to the above, a qubit to be moved and a qubit to be operated on can be placed in a fixed arithmetic operation area (e.g., a specific area widely reserved for arithmetic operations). This makes it possible to perform efficient qubit operations.

Further, the electron configuration method according to the present embodiment may, when a predetermined qubit moves in the qubit array, cause the quantum computer to simultaneously move the other qubits in the same column or row as the predetermined qubit in the same direction as the predetermined qubit.

According to the above, the qubits in each column and each row can be moved based on the principle of simultaneous movement.

In addition, the electron configuration method according to the present embodiment may, when the above-mentioned other qubits simultaneously move in the qubit array, cause the quantum computer to exercise block control in such a manner that only specific qubits among the other qubits remain in the original position without being moved, and define and operate the bus area as an area parallel to the direction of movement in which the block control can be exercised.

According to the above, what is generally called block control can be applied to electron movement operations, so that, for example, more flexible movement route selection is likely to be possible.

What is claimed is:

1. An electron configuration method used by a quantum computer that includes a bus area, an aisle area, and a seat area in a qubit array formed by a plurality of quantum dots capable of storing electrons, the bus area transversely or longitudinally crossing the qubit array, the aisle area being orthogonal to the bus area in the qubit array, and the seat area being positioned between the bus area and the aisle area and used as an area where qubits are arranged, the electron configuration method comprising:
in an environment where the seat area and the bus area are connected by the aisle area, causing the quantum computer to move a first qubit initially arranged in a predetermined seat area to the bus area through the aisle area connected to the seat area, and move the first qubit through the bus area to a position adjacent to a second qubit to be operated on.

2. The electron configuration method according to claim 1, further comprising:
when moving the first qubit, causing the quantum computer to move the first qubit to an aisle area connected to a seat area of the second qubit through the bus area and move the first qubit to a position adjacent to the second qubit through the aisle area.

3. The electron configuration method according to claim 1, further comprising:
causing the quantum computer to move the second qubit to the bus area through an aisle area connected to the seat area and, in the bus area, place the second qubit adjacent to the first qubit.

4. The electron configuration method according to claim 1, further comprising:
causing the quantum computer to move the first qubit to the bus area through an aisle area connected to the seat area, and move the first qubit through the bus area to the aisle area connected to a seat area of the second qubit;
causing the quantum computer to move the second qubit to the aisle area connected to the seat area; and
causing the quantum computer to place the first qubit and the second qubit adjacent to each other in the aisle area connected to the seat area of the second qubit.

5. The electron configuration method according to claim 1, further comprising:
causing the quantum computer to retain, in the qubit array, an arithmetic operation area where arithmetic operations are allowed to be performed on qubits; and
causing the quantum computer to move the first qubit to the bus area through an aisle area connected to the seat area, then move the first qubit to the arithmetic operation area through the bus area, move the second qubit to the bus area through the aisle area connected to the seat area, then move the second qubit to the arithmetic operation area through the bus area, and thus, in the arithmetic operation area, place the second qubit adjacent to the first qubit.

6. The electron configuration method according to claim 1, further comprising:
when a predetermined qubit moves in the qubit array, causing the quantum computer to simultaneously move other qubits in a same column or row as the predetermined qubit in a same direction as the predetermined qubit.

7. The electron configuration method according to claim 6, further comprising:
when the other qubits simultaneously move in the qubit array, causing the quantum computer to exercise block control in such a manner that only specific qubits among the other qubits remain in the original position without being moved, and define and operate the bus area as an area parallel to a direction of movement in which the block control can be exercised.

8. An electron configuration device formed by a quantum computer, the electron configuration device comprising:
a bus area, an aisle area, and a seat area in a qubit array formed by a plurality of quantum dots capable of storing electrons, the bus area transversely or longitudinally crosses the qubit array, the aisle area is orthogonal to the bus area in the qubit array, and the seat area is positioned between the bus area and the aisle area and used as an area where qubits are arranged, wherein,
in an environment where the seat area and the bus area are connected by the aisle area, the electron configuration device allows a first qubit initially arranged in a predetermined seat area to reach the bus area through an aisle area connected to the seat area, and moves the first qubit through the bus area to a position adjacent to a second qubit to be operated on.
